(19) United States
(12) Patent Application Publication
(10) Pub. No.: US 2025/0286514 A1
(43) Pub. Date: Sep. 11, 2025

(54) HIGH FREQUENCY AMPLIFIER

(71) Applicant: SUMITOMO ELECTRIC INDUSTRIES, LTD., Osaka (JP)

(72) Inventor: Tatsuya HASHINAGA, Osaka (JP)

(21) Appl. No.: 19/063,747

(22) Filed: Feb. 26, 2025

(30) Foreign Application Priority Data
Mar. 7, 2024 (JP) 2024-035307

(51) Int. Cl. H03F 1/02; H03F 3/24

(52) U.S. Cl. CPC H03F 1/0288; H03F 3/245; H03F 2200/451

(57) ABSTRACT

A high frequency amplifier includes a driver amplifier that amplifies an input high frequency signal and an asymmetrical Doherty amplifier that amplifies a high frequency signal output from the driver amplifier. The high frequency amplifier includes a first layered structure, a second layered structure layered on the first layered structure, and a third layered structure layered on the second layered structure. The asymmetrical Doherty amplifier includes a carrier amplifier, a peak amplifier, a branch circuit, a first signal line, a second signal line, and a phase adjusting circuit. The second layered structure includes a first wiring layer, a second wiring layer, a dielectric layer, and one or more capacitors. The driver amplifier, the carrier amplifier, and the peak amplifier are provided in the first layered structure. The branch circuit and the phase adjusting circuit are provided in the third layered structure.

### CROSS REFERENCE TO RELATED APPLICATIONS

This application claims priority based on Japanese Patent Application No. 2024-035307 filed on Mar. 7, 2024, and the entire contents of the Japanese patent application are incorporated herein by reference.

### TECHNICAL FIELD

The present disclosure relates to a high frequency amplifier.

### BACKGROUND

In recent years, broader bandwidths of mobile communication systems, such as mobile phones, are developed. Thus, for a power amplifier used in base station equipment of the system and the like, it is desirable to improve the power efficiency in a high frequency band and the like. As power amplifiers for achieving the improvement of the power efficiency, an asymmetrical Doherty amplifier including a carrier amplifier and a peak amplifier is known. The carrier amplifier may be referred to as a main amplifier. The asymmetrical Doherty amplifier is connected at a stage following a driver amplifier. Further, a high frequency amplifier in which a driver amplifier, a carrier amplifier, and a peak amplifier are three-dimensionally mounted has been proposed.
Patent literature 1: Japanese Unexamined Patent Application Publication No. 2021-170703

### SUMMARY

A high frequency amplifier of the present disclosure includes a driver amplifier configured to amplify an input high frequency signal and an asymmetrical Doherty amplifier configured to amplify a high frequency signal output from the driver amplifier. The high frequency amplifier includes a first layered structure, a second layered structure layered on the first layered structure, and a third layered structure layered on the second layered structure. The asymmetrical Doherty amplifier includes: a carrier amplifier; a peak amplifier configured to initiate an amplifying operation in a case where an output of the carrier amplifier has reached a saturation region, the peak amplifier having a saturation output different from a saturation output of the carrier amplifier; a branch circuit configured to receive the high frequency signal output from the driver amplifier; a first signal line provided between the branch circuit and the carrier amplifier; a second signal line provided between the branch circuit and the peak amplifier; and a phase adjusting circuit provided in either one or both of the first signal line and the second signal line and configured to delay either one or both of a phase of an input signal to the carrier amplifier and a phase of an input signal to the peak amplifier. The branch circuit is configured to branch the high frequency signal output from the driver amplifier into the first signal line and the second signal line. The second layered structure includes: a first wiring layer provided between the first layered structure and the third layered structure; a second wiring layer provided between the first wiring layer and the third layered structure; a dielectric layer provided between the first wiring layer and the second wiring layer; and one or more capacitors including a part of the first wiring layer, a part of the second wiring layer, and a part of the dielectric layer. The driver amplifier, the carrier amplifier, and the peak amplifier are provided in the first layered structure. The branch circuit and the phase adjusting circuit are provided in the third layered structure. The one or more capacitors are each electrically connected to any one of the driver amplifier, the carrier amplifier, and the peak amplifier.

### BRIEF DESCRIPTION OF THE DRAWINGS

FIG. 1 is a block diagram illustrating a high frequency amplifier according to an embodiment.

FIG. 2 is a circuit diagram illustrating a configuration of a driver amplifier, an input matching circuit, an output matching circuit, and an output bias circuit.

FIG. 3 is a circuit diagram illustrating a configuration of an asymmetrical Doherty amplifier.

FIG. 4 is a cross-sectional view of a high frequency amplifier according to the embodiment.

FIG. 5 is a first diagram illustrating a layout of a wiring layer.

FIG. 6 is a second diagram illustrating a layout of a wiring layer.

FIG. 7 is a third diagram illustrating a layout of a wiring layer.

FIG. 8 is a fourth diagram illustrating a layout of a wiring layer.

FIG. 9 is a fifth diagram illustrating a layout of a wiring layer.

FIG. 10 is a sixth diagram illustrating a layout of a wiring layer.

FIG. 11 is a first cross-sectional view illustrating a method of manufacturing a high frequency amplifier according to the embodiment.

FIG. 12 is a second cross-sectional view illustrating a method of manufacturing a high frequency amplifier according to the embodiment.

FIG. 13 is a third cross-sectional view illustrating a method of manufacturing a high frequency amplifier according to the embodiment.

FIG. 14 is a fourth cross-sectional view illustrating a method of manufacturing a high frequency amplifier according to the embodiment.

FIG. 15 is a fifth cross-sectional view illustrating a method of manufacturing a high frequency amplifier according to the embodiment.

FIG. 16 is a sixth cross-sectional view illustrating a method of manufacturing a high frequency amplifier according to the embodiment.

FIG. 17 is a seventh cross-sectional view illustrating a method of manufacturing a high frequency amplifier according to the embodiment.

FIG. 18 is a diagram illustrating a layout in a first example.

FIG. 19 is a diagram illustrating a layout in a second example.

### DETAILED DESCRIPTION

In recent years, there has been an increasing demand for improvement in high frequency characteristics of a high frequency amplifier.

According to the present disclosure, high frequency characteristics can be improved.

### Description of Embodiments of Present Disclosure

First, embodiments of the present disclosure will be listed and described.

(1) A high frequency amplifier according to an aspect of the present disclosure includes a driver amplifier configured to amplify an input high frequency signal and an asymmetrical Doherty amplifier configured to amplify a high frequency signal output from the driver amplifier. The high frequency amplifier includes a first layered structure, a second layered structure layered on the first layered structure, and a third layered structure layered on the second layered structure. The asymmetrical Doherty amplifier includes: a carrier amplifier; a peak amplifier configured to initiate an amplifying operation in a case where an output of the carrier amplifier has reached a saturation region, the peak amplifier having a saturation output different from a saturation output of the carrier amplifier; a branch circuit configured to receive the high frequency signal output from the driver amplifier; a first signal line provided between the branch circuit and the carrier amplifier; a second signal line provided between the branch circuit and the peak amplifier; and a phase adjusting circuit provided in either one or both of the first signal line and the second signal line and configured to delay either one or both of a phase of an input signal to the carrier amplifier and a phase of an input signal to the peak amplifier. The branch circuit is configured to branch the high frequency signal output from the driver amplifier into the first signal line and the second signal line. The second layered structure includes: a first wiring layer provided between the first layered structure and the third layered structure; a second wiring layer provided between the first wiring layer and the third layered structure; a dielectric layer provided between the first wiring layer and the second wiring layer; and one or more capacitors including a part of the first wiring layer, a part of the second wiring layer, and a part of the dielectric layer. The driver amplifier, the carrier amplifier, and the peak amplifier are provided in the first layered structure. The branch circuit and the phase adjusting circuit are provided in the third layered structure. The one or more capacitors are each electrically connected to any one of the driver amplifier, the carrier amplifier, and the peak amplifier.

A capacitor including a part of the first wiring layer, a part of the second wiring layer, and a part of the dielectric layer is provided between the driver amplifier, the carrier amplifier, and the peak amplifier, and the branch circuit and the phase adjusting circuit. Thus, signal interference is less likely to occur between the driver amplifier, the carrier amplifier, and the peak amplifier, and the branch circuit and the phase adjusting circuit, and the high frequency characteristics can be improved.

(2) In (1), the high frequency amplifier may further include a first input matching circuit including the one or more capacitors and connected to an input terminal of the driver amplifier. In this case, the number of surface mount components included in the first input matching circuit can be reduced.

(3) In (2), the first input matching circuit may be provided in the first layered structure and the second layered structure. In this case, a part of the first wiring layer may be used as an electrode of the capacitor included in the first input matching circuit.

(4) In any one of (1) to (3), the high frequency amplifier may further include a second input matching circuit including the one or more capacitors and connected to an input terminal of the carrier amplifier. In this case, the number of surface mount components included in the second input matching circuit can be reduced.

(5) In (4), the second input matching circuit may be provided in the first layered structure and the second layered structure. In this case, a part of the first wiring layer may be used as an electrode of the capacitor included in the second input matching circuit.

(6) In any one of (1) to (5), the high frequency amplifier may further include a third input matching circuit including the one or more capacitors and connected to an input terminal of the peak amplifier. In this case, the number of surface mount components included in the third input matching circuit can be reduced.

(7) In (6), the third input matching circuit may be provided in the first layered structure and the second layered structure. In this case, a part of the first wiring layer may be used as an electrode of the capacitor included in the third input matching circuit.

(8) In any one of (1) to (7), the first wiring layer may have a ground region overlapping, in a plan view, at least with a transmission line through which a high frequency signal output from the carrier amplifier or the peak amplifier is transmitted. In particular, the high frequency signal output from the carrier amplifier or the peak amplifier is likely to be affected by the parasitic capacitance, but the ground region is provided, and thus it is easy to reduce deterioration of the high frequency signal due to the parasitic capacitance.

(9) In any one of (1) to (8), when n is an integer of 0 or more, an electrical length from an output terminal of the driver amplifier to an input terminal of the carrier amplifier may be within a range of (2n+1)×π−π/2 to (2n+1)×π+π/2 in terms of a phase of the high frequency signal. In this case, even when the driver amplifier and the carrier amplifier are close to each other, the electrical characteristics of the carrier amplifier can be easily stabilized.

(10) In any one of (1) to (9), when n is an integer of 0 or more, an electrical length from an output terminal of the driver amplifier to an input terminal of the peak amplifier may be within a range of (2n+1)×π−π/2 to (2n+1)×π+π/2 in terms of a phase of the high frequency signal. In this case, even when the driver amplifier and the peak amplifier are close to each other, the electrical characteristics of the carrier amplifier can be easily stabilized.

(11) In any one of (1) to (10), the saturation output of the peak amplifier may be larger than the saturation output of the carrier amplifier. In the peak amplifier, the phase shift amount for obtaining the optimum matching is larger than that in the carrier amplifier.

### Details of Embodiments of Present Disclosure

Hereinafter, embodiments of the present disclosure will be described in detail, but the present disclosure is not limited thereto. In the specification and the drawings, components having substantially the same functional configuration are denoted by the same reference numerals, and redundant description thereof may be omitted. In the following description, an XYZ orthogonal coordinate system is used. However, the coordinate system is defined for description and does not limit the posture of the semiconductor device. Further, when viewed from an arbitrary point, a +Z side may be referred to as an upward side, an upper side, or a top, and a −Z side may be referred to as a downward side, a lower side, or a bottom.

### (Circuit of High Frequency Amplifier)

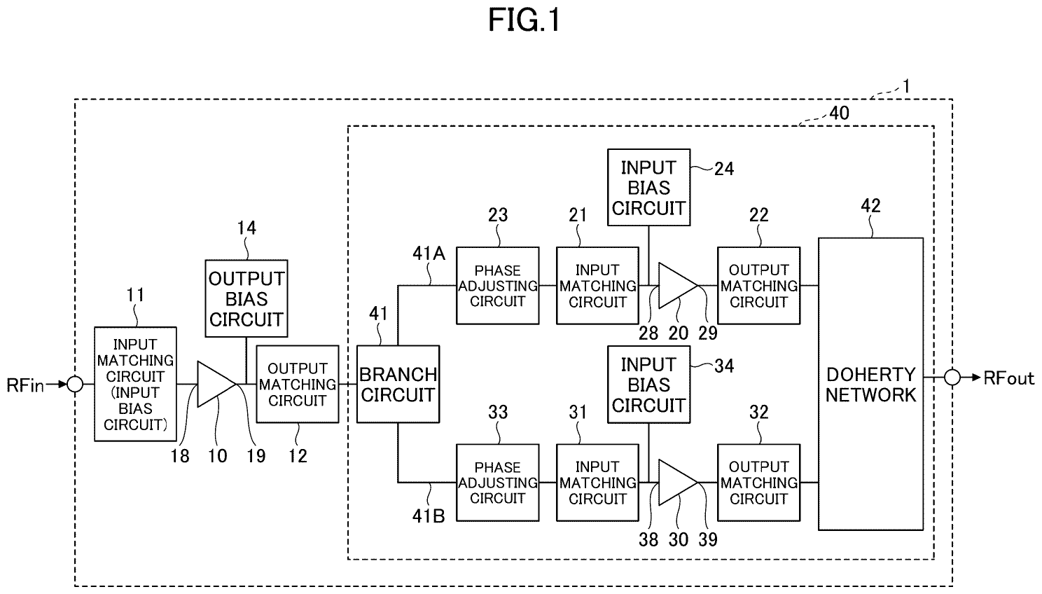

First, a circuit of a high frequency amplifier according to an embodiment will be described. FIG. 1 is a block diagram illustrating a high frequency amplifier according to the embodiment.

A high frequency amplifier 1 according to the embodiment is mounted in a communication device, such as base station equipment of a mobile communication system. High frequency amplifier 1 is used to amplify a transmission signal, for example. High frequency amplifier 1 amplifies, for example, radio frequency (RF) signals having a frequency of about 5 GHz to 6 GHz.

Focusing on the circuit configuration, as illustrated in FIG. 1, high frequency amplifier 1 includes an input terminal RFin, an output terminal RFout, a driver amplifier 10, and an asymmetrical Doherty amplifier 40. Asymmetrical Doherty amplifier 40 includes a branch circuit 41, a first signal line 41A, a second signal line 41B, a carrier amplifier 20, and a peak amplifier 30. High frequency amplifier 1 further includes an input matching circuit 11, an output matching circuit 12, and an output bias circuit 14. Asymmetrical Doherty amplifier 40 further includes a phase adjusting circuit 23, an input matching circuit 21, an output matching circuit 22, an input bias circuit 24, a phase adjusting circuit 33, an input matching circuit 31, an output matching circuit 32, an input bias circuit 34, and a Doherty network 42.

Input matching circuit 11 is connected to input terminal RFin. Input matching circuit 11 also functions as an input bias circuit. Input matching circuit 11 is connected to an input terminal 18 of driver amplifier 10, and output matching circuit 12 and output bias circuit 14 are connected to an output terminal 19 of driver amplifier 10. An RF signal is input to driver amplifier 10 from input terminal RFin via input matching circuit 11, and driver amplifier 10 amplifies the input RF signal. Driver amplifier 10 amplifies the RF signal to such an extent that asymmetrical Doherty amplifier 40 can amplify the RF signal to a predetermined transmission power, for example. The RF signal amplified by driver amplifier 10 is output via output matching circuit 12. Input matching circuit 11 is an example of a first input matching circuit.

The RF signal output via output matching circuit 12 is input to branch circuit 41. First signal line 41A is provided between branch circuit 41 and carrier amplifier 20, and second signal line 41B is provided between branch circuit 41 and peak amplifier 30. Branch circuit 41 branches the input RF signal into first signal line 41A and second signal line 41B. For example, branch circuit 41 is a Wilkinson type divider, and equally branches the RF signal amplified by driver amplifier 10 into first signal line 41A and second signal line 41B.

Phase adjusting circuit 23 and input matching circuit 21 are provided in first signal line 41A. Input matching circuit 21 and input bias circuit 24 are connected to an input terminal 28 of carrier amplifier 20, and output matching circuit 22 is connected to an output terminal 29 of carrier amplifier 20. Phase adjusting circuit 23 delays the phase of a signal (an input signal to carrier amplifier 20) output from branch circuit 41 to first signal line 41A. The RF signal is input to carrier amplifier 20 via input matching circuit 21, and carrier amplifier 20 amplifies the input RF signal. The RF signal amplified by carrier amplifier 20 is output via output matching circuit 22. Input matching circuit 21 is an example of a second input matching circuit.

Phase adjusting circuit 33 and input matching circuit 31 are provided in second signal line 41B. Input matching circuit 31 and input bias circuit 34 are connected to an input terminal 38 of peak amplifier 30, and output matching circuit 32 is connected to an output terminal 39 of peak amplifier 30. Phase adjusting circuit 33 delays the phase of a signal (an input signal to peak amplifier 30) output from branch circuit 41 to second signal line 41B. The RF signal is input to peak amplifier 30 via input matching circuit 31 and peak amplifier 30 amplifies the input RF signal. Peak amplifier 30 initiates an amplifying operation in a case where an output of carrier amplifier 20 has reached a saturation region, and has a saturation output different from a saturation output of carrier amplifier 20. The RF signal amplified by peak amplifier 30 is output via output matching circuit 32. Input matching circuit 31 is an example of a third input matching circuit.

The RF signal output via output matching circuit 22 and the RF signal output via output matching circuit 32 are input to Doherty network 42.

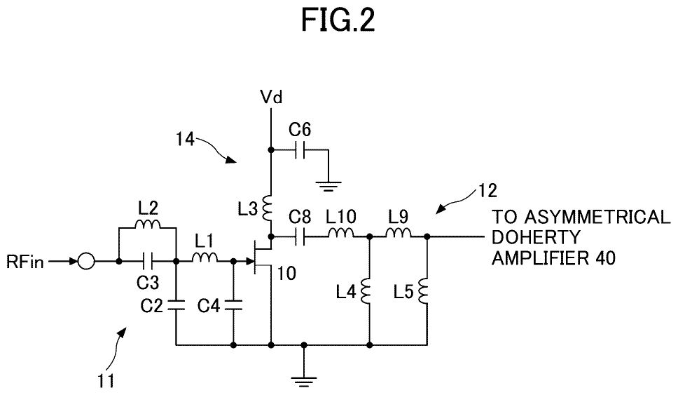

Next, a circuit configuration of driver amplifier 10, input matching circuit 11, output matching circuit 12, and output bias circuit 14 will be described. FIG. 2 is a circuit diagram illustrating a configuration of driver amplifier 10, input matching circuit 11, output matching circuit 12, and output bias circuit 14.

Input matching circuit 11 includes capacitors C2, C3, and C4 and inductors L1 and L2. Capacitor C3 and inductor L1 are connected in series to input terminal RFin in this order. A gate of driver amplifier 10 is connected to a stage following inductor L1. Inductor L2 is connected in parallel to capacitor C3. Capacitor C2 is connected between the ground and a node between capacitor C3 and inductor L1. Capacitor C4 is connected between the ground and a node between inductor L1 and the gate of driver amplifier 10.

Output matching circuit 12 includes a capacitor C8 and inductors L4, L5, L9 and L10. Capacitor C8, inductor L10, and inductor L9 are connected in series to the drain of driver amplifier 10 in this order. Inductor L4 is connected between the ground and a node between inductor L10 and inductor L9. Inductor L5 is connected between inductor L9 and the ground in a stage following inductor L9.

Output bias circuit 14 includes a capacitor C6 and an inductor L3. Inductor L3 is connected between a node to which a voltage Vd is input and the drain of driver amplifier 10. Capacitor C6 is connected between a node to which voltage Vd is input and the ground. Voltage Vd is supplied as a drain bias of driver amplifier 10 via inductor L3. Capacitor C6 is a bypass capacitor for voltage Vd.

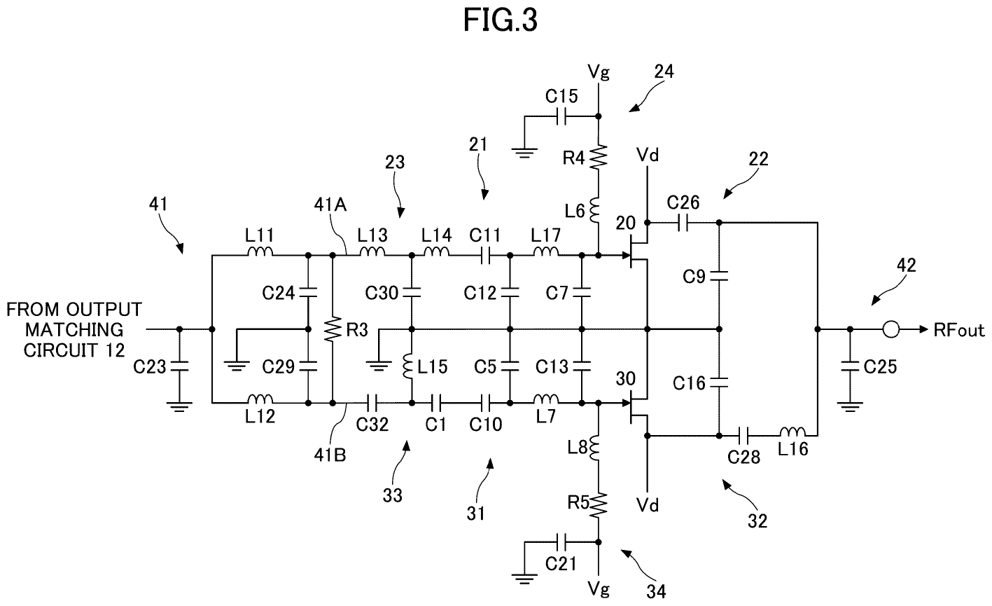

Next, asymmetrical Doherty amplifier 40 will be described. Asymmetrical Doherty amplifier 40 further amplifies the RF signal amplified by driver amplifier 10 and outputs the amplified RF signal from output terminal RFout. FIG. 3 is a circuit diagram illustrating a configuration of asymmetrical Doherty amplifier 40.

As described above, asymmetrical Doherty amplifier 40 includes branch circuit 41, first signal line 41A, second signal line 41B, carrier amplifier 20, peak amplifier 30, phase adjusting circuit 23, input matching circuit 21, output matching circuit 22, input bias circuit 24, phase adjusting circuit 33, input matching circuit 31, output matching circuit 32, input bias circuit 34, and Doherty network 42.

Branch circuit 41 includes capacitors C23, C24, and C29, inductors L11 and L12, and a resistor element R3. Inductor L11 is connected between output matching circuit 12 and phase adjusting circuit 23. Inductor L12 is connected between output matching circuit 12 and phase adjusting circuit 33. Capacitor C23 is connected between the ground and a node between output matching circuit 12 and inductors L11 and L12. Capacitor C24 is connected between inductor L11 and the ground at a stage following inductor L11. Capacitor C29 is connected between inductor L12 and the ground at a stage following inductor L12. Resistor element R3 is connected between inductor L11 and inductor L12 at a stage following capacitors C24 and C29.

Phase adjusting circuit 23 includes a capacitor C30 and inductors L13 and L14. Inductors L13 and L14 are connected in series to inductor L11 in this order. Capacitor C30 is connected between the ground and a node between inductor L13 and inductor L14.

Phase adjusting circuit 33 includes capacitors C32 and C1 and an inductor L15. Capacitors C32 and C1 are connected in series to inductor L12 in this order. Inductor L15 is connected between the ground and a node between capacitor C32 and capacitor C1.

Input matching circuit 21 includes capacitors C11, C12, and C7 and an inductor L17. Capacitor C11 and inductor L17 are connected in series to inductor L14 in this order. A gate of carrier amplifier 20 is connected to a stage following inductor L17. Capacitor C12 is connected between the ground and a node between capacitor C11 and inductor L17. Capacitor C7 is connected between the ground and a node between inductor L17 and the gate of carrier amplifier 20.

Input bias circuit 24 includes a capacitor C15, a resistor element R4, and an inductor L6. Resistor element R4 and inductor L6 are connected in series in this order between a power source Vg and the gate of carrier amplifier 20. Capacitor C15 is connected between the ground and a node between power source Vg and resistor element R4. A gate bias of carrier amplifier 20 is supplied from power source Vg via inductor L6. Capacitor C15 is a bypass capacitor of power source Vg, and resistor element R4 is a resistor for adjustment.

Input matching circuit 31 includes capacitors C10, C5, and C13 and an inductor L7. Capacitor C10 and inductor L7 are connected in series to capacitor C1 in this order. A gate of peak amplifier 30 is connected to a stage following inductor L7. Capacitor C5 is connected between the ground and a node between capacitor C10 and inductor L7. Capacitor C13 is connected between the ground and a node between inductor L7 and the gate of peak amplifier 30.

Input bias circuit 34 includes a capacitor C21, a resistor element R5, and an inductor L8. Resistor element R5 and inductor L8 are connected in series in this order between power source Vg and the gate of peak amplifier 30. Capacitor C21 is connected between the ground and a node between power source Vg and resistor element R5.

Output matching circuit 22 includes capacitors C9 and C26. Capacitor C26 is connected between the drain of carrier amplifier 20 and Doherty network 42. Capacitor C26 is a capacitor for blocking a DC component. Capacitor C9 is connected between the ground and a node between capacitor C26 and Doherty network 42. Voltage Vd is supplied from an external output bias circuit as a drain bias of carrier amplifier 20.

Output matching circuit 32 includes a capacitors C28 and C16 and an inductor L16. Capacitor C28 and inductor L16 are connected in series in this order between the drain of peak amplifier 30 and Doherty network 42. Capacitor C28 is a capacitor for blocking a DC component. Capacitor C16 is connected between the ground and a node between the drain of peak amplifier 30 and capacitor C28. Voltage Vd is supplied from an external output bias circuit as a drain bias of peak amplifier 30.

Doherty network 42 includes a capacitor C25. Capacitor C25 is connected between the ground and a node between output terminal RFout, capacitor C26 and inductor L16.

### (Structure of High Frequency Amplifier)

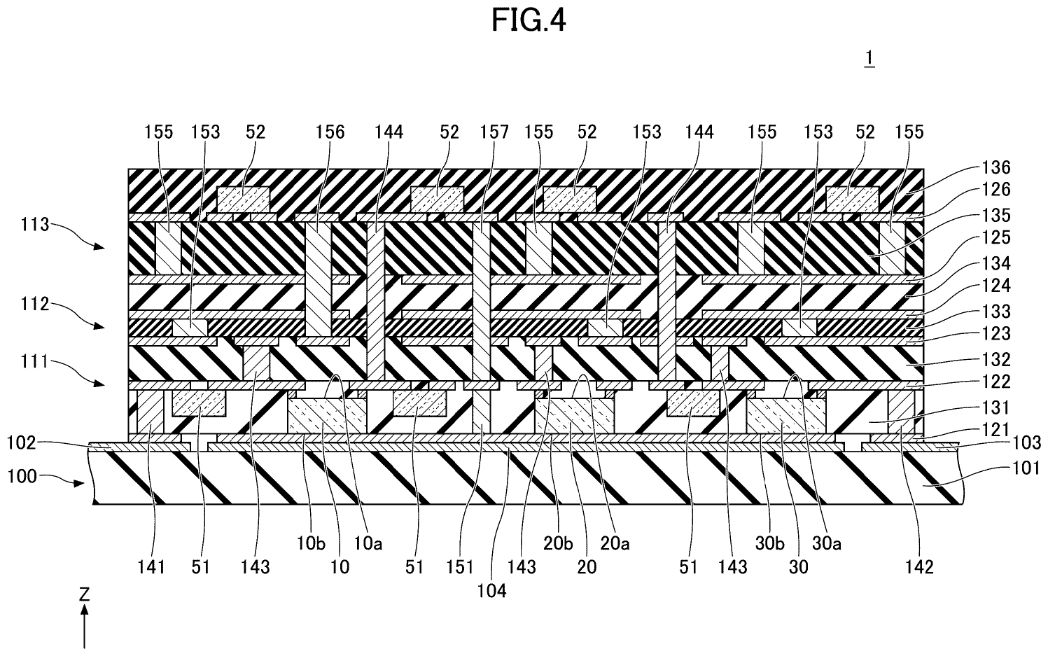

Next, the structure of high frequency amplifier 1 according to the embodiment will be described. FIG. 4 is a cross-sectional view of a high frequency amplifier according to the embodiment. Note that FIG. 4 illustrates a schematic cross section of high frequency amplifier 1, and the arrangement of driver amplifier 10, carrier amplifier 20, peak amplifier 30, the surface mount component, the transmission line pattern, and the conductive via does not correspond to the circuits illustrated in FIGS. 1 to 3.

Focusing on the cross-sectional configuration, as illustrated in FIG. 4, high frequency amplifier 1 includes a first layered structure 111, a second layered structure 112, and a third layered structure 113. Second layered structure 112 is provided on or over first layered structure 111, and third layered structure 113 is provided on or over second layered structure 112. First layered structure 111, second layered structure 112, and third layered structure 113 have, for example, a square planar shape with each side having a length of, for example, 6 mm.

First layered structure 111 includes a wiring layer 121, a dielectric layer 131, a wiring layer 122, a dielectric layer 132, driver amplifier 10, carrier amplifier 20, peak amplifier 30, and a plurality of surface mount components 51.

Wiring layer 122 is provided on the lower surface of dielectric layer 132. A thickness of dielectric layer 132 is, for example, 0.1 mm to 0.2 mm. For example, dielectric layer 132 has a relative dielectric constant of 3.0 to 3.7 and a dielectric loss tangent of 0.002 to 0.007. A thickness of wiring layer 122 is, for example, 10 μm to 45 μm. The thickness of wiring layer 122 may be 35 μm to 45 μm. Wiring layer 122 is, for example, a copper layer. As will be described in detail later, a transmission line pattern and a ground pattern are formed in wiring layer 122. The conductivity of copper is about 6.25×10¹⁷ S/m.

Driver amplifier 10 is mounted on the lower surface of wiring layer 122. Driver amplifier 10 is, for example, an amplifier including a gallium nitride (GaN)-based high electron mobility transistor (HEMT). Driver amplifier 10 includes a substrate and a semiconductor layer provided on or over the substrate. Driver amplifier 10 has a three dimensional shape of a rectangular parallelepiped shape including a main surface 10a and a main surface 10b opposite to main surface 10a. Main surface 10a is in the semiconductor layer, and main surface 10b is in the substrate. An amplifier circuit including a semiconductor layer is formed on main surface 10a. In main surface 10a, a gate pad is provided in the vicinity of one of two sides parallel to each other, and a drain pad is provided in the vicinity of the other side. Further, source pads are provided on both sides of the gate pad, and the source pads are connected to electrodes provided on main surface 10b. Main surface 10a faces upward, and main surface 10b faces downward.

Carrier amplifier 20 is mounted on the lower surface of wiring layer 122. Carrier amplifier 20 is, for example, an amplifier including a GaN-based HEMT. Carrier amplifier 20 includes a substrate and a semiconductor layer provided on or over the substrate. Carrier amplifier 20 has a three dimensional shape of a rectangular parallelepiped shape including a main surface 20a and a main surface 20b opposite to main surface 20a. Main surface 20a is in the semiconductor layer, and main surface 20b is in the substrate. An amplifier circuit including a semiconductor layer is formed on main surface 20a. In main surface 20a, a gate pad is provided in the vicinity of one of two sides parallel to each other, and a drain pad is provided in the vicinity of the other side. Further, source pads are provided on both sides of the gate pad, and the source pads are connected to electrodes provided on main surface 20b. Main surface 20a faces upward, and main surface 20b faces downward.

Peak amplifier 30 is mounted on the lower surface of wiring layer 122. Peak amplifier 30 is, for example, an amplifier including a GaN-based HEMT. Peak amplifier 30 includes a substrate and a semiconductor layer provided on or over the substrate. Peak amplifier 30 has a three dimensional shape of a rectangular parallelepiped including a main surface 30a and a main surface 30b opposite to main surface 30a. Main surface 30a is in the semiconductor layer, and main surface 30b is in the substrate. An amplifier circuit including the semiconductor layer is formed on main surface 30a. In main surface 30a, a gate pad is provided in the vicinity of one of two sides parallel to each other, and a drain pad is provided in the vicinity of the other side. Further, source pads are provided on both sides of the gate pad, and the source pads are connected to electrodes provided on main surface 30b. Main surface 30a faces upward, and main surface 30b faces downward.

Surface mount component 51 is, for example, a capacitor, an inductor, or a resistor element. Surface mount component 51 is mounted on the lower surface of wiring layer 122.

Dielectric layer 131 is provided under dielectric layer 132. Dielectric layer 131 covers the lower surfaces of wiring layer 122 and surface mount component 51. Dielectric layer 131 covers the side surface of driver amplifier 10, the side surface of carrier amplifier 20, and the side surface of peak amplifier 30 from the side. Main surface 10b of driver amplifier 10, main surface 20b of carrier amplifier 20, and main surface 30b of peak amplifier 30 are not covered with dielectric layer 131 and are exposed from dielectric layer 131. A thickness of dielectric layer 131 is, for example, 0.3 mm to 0.4 mm. Dielectric layer 131 has, for example, a relative dielectric constant of 3.0 to 3.7, and a dielectric loss tangent of 0.002 to 0.007.

Wiring layer 121 is provided on the lower surface of dielectric layer 131. A thickness of wiring layer 121 is, for example, 10 μm to 120 μm. A thickness of wiring layer 121 may be 80 μm to 120 μm. Wiring layer 121 is, for example, a copper layer. As will be described in detail later, a transmission line pattern and a ground pattern are formed in wiring layer 121.

Second layered structure 112 includes a wiring layer 123, a dielectric layer 133, and a wiring layer 124. Wiring layer 123 is provided on the lower surface of dielectric layer 133, and wiring layer 124 is provided on the upper surface of dielectric layer 133. Dielectric layer 133 is provided between wiring layer 123 and wiring layer 124.

Wiring layer 123 is provided on or over dielectric layer 132. A thickness of wiring layer 123 is, for example, 10 μm to 35 μm. A thickness of wiring layer 123 may be 10 μm to 18 μm. Wiring layer 123 is, for example, a copper layer. As will be described in detail later, an electrode pattern of a capacitor and a ground pattern are formed in wiring layer 123. The ground pattern is formed in a solid state apart from the electrode pattern. Wiring layer 123 is an example of a first wiring layer.

A thickness of dielectric layer 133 is, for example, 1 μm to 24 μm. For example, dielectric layer 133 has a relative dielectric constant of 7.0 to 10.0 and a dielectric loss tangent of 0.01 to 0.03.

A thickness of wiring layer 124 is, for example, 10 μm to 35 μm. A thickness of wiring layer 124 may be 10 μm to 18 μm. Wiring layer 124 is, for example, a copper layer. As will be described in detail later, a ground pattern is formed in a solid state in wiring layer 124. Wiring layer 124 is an example of a second wiring layer.

Third layered structure 113 includes a dielectric layer 134, a wiring layer 125, a dielectric layer 135, a wiring layer 126, a dielectric layer 136, and a plurality of surface mount components 52. Wiring layer 125 is provided on the lower surface of dielectric layer 135, and wiring layer 126 is provided on the upper surface of dielectric layer 135. Dielectric layer 135 is provided between wiring layer 125 and wiring layer 126.

A thickness of dielectric layer 135 is, for example, 0.1 mm to 0.2 mm. For example, dielectric layer 135 has a relative dielectric constant of 3.0 to 3.7 and a dielectric loss tangent of 0.002 to 0.007. A thickness of wiring layer 125 is, for example, 10 μm to 35 μm. The thickness of wiring layer 125 may be 20 μm to 35 μm. A thickness of wiring layer 126 is, for example, 10 μm to 45 μm. The thickness of wiring layer 126 may be 30 μm to 45 μm. Wiring layers 125 and 126 are, for example, copper layers. As will be described in detail later, a ground pattern is formed in a solid state in wiring layer 125, and a transmission line pattern and a ground pattern are formed in wiring layer 126.

Dielectric layer 134 is provided between dielectric layer 133 and dielectric layer 135, covers the upper surface of wiring layer 124, and covers the lower surface of wiring layer 125. A thickness of dielectric layer 134 is, for example, 0.1 mm to 0.2 mm. For example, dielectric layer 134 has a relative dielectric constant of 3.0 to 3.7 and a dielectric loss tangent of 0.002 to 0.007.

Surface mount component 52 is, for example, a capacitor, an inductor, or a resistor element. Surface mount component 52 is mounted on the upper surface of wiring layer 126.

Dielectric layer 136 is provided on or over dielectric layer 135. Dielectric layer 136 covers the upper surfaces of wiring layer 126 and surface mount component 52. A thickness of dielectric layer 136 is, for example, 0.4 mm to 1.0 mm. For example, dielectric layer 136 has a relative dielectric constant of 3.0 to 4.0 and a dielectric loss tangent of 0.002 to 0.012.

Conductive vias 141 and 142 for signal transmission and a conductive via 151 for grounding are provided in dielectric layer 131. Conductive vias 141, 142, and 151 electrically connect a part of wiring layer 121 and a part of wiring layer 122, respectively. The part of wiring layer 121 to which conductive via 141 is connected is used as input terminal RFin, and the part of wiring layer 121 to which conductive via 142 is connected is used as output terminal RFout. The part of wiring layer 121 to which conductive via 151 is connected is used as a ground terminal to which a ground potential is applied.

At least one conductive via 143 for signal transmission is provided in dielectric layer 132. Conductive via 143 electrically connects a part of wiring layer 122 and a part of wiring layer 123.

At least one conductive via 153 for grounding is provided in dielectric layer 133. Conductive via 153 electrically connects a part of wiring layer 123 and a part of wiring layer 124.

At least one conductive via 155 for grounding is provided in dielectric layer 135. Conductive via 155 electrically connects a part of wiring layer 125 and a part of wiring layer 126.

A conductive via 156 for grounding is provided in dielectric layers 133, 134, and 135. Conductive via 156 electrically connects a part of wiring layer 123, a part of wiring layer 124, a part of wiring layer 125, and a part of wiring layer 126.

Dielectric layers 132, 133, 134, and 135 are provided with at least one conductive via 144 for signal transmission and a conductive via 157 for grounding. Conductive via 144 electrically connects a part of wiring layer 122 and a part of wiring layer 126. Conductive via 144 may be further electrically connected to a part of wiring layer 123. Conductive via 157 electrically connects a part of wiring layer 122, a part of wiring layer 123, a part of wiring layer 124, a part of wiring layer 125, and a part of wiring layer 126.

A strip line is formed by a transmission line pattern formed in wiring layer 122, a ground pattern formed in wiring layer 123, and a part of dielectric layer 132 therebetween. In addition, a strip line is formed by a transmission line pattern formed in wiring layer 126, a ground pattern formed in wiring layer 125, and a part of dielectric layer 135 therebetween. The ground pattern formed in wiring layers 123, 124, or 125 blocks the propagation of the electromagnetic wave generated in first layered structure 111 to third layered structure 113, and blocks the propagation of the electromagnetic wave generated in third layered structure 113 to first layered structure 111.

In second layered structure 112, the electrode pattern formed in wiring layer 123 is not electrically connected to wiring layer 124, and a thin film capacitor is formed by the electrode pattern formed in wiring layer 123, the ground pattern formed in wiring layer 124, and a part of dielectric layer 133 therebetween.

High frequency amplifier 1 is mounted on, for example, a printed circuit board 100 of a communication device. Printed circuit board 100 includes a base 101, a signal wiring 102 to which input terminal RFin is connected, a signal wiring 103 to which output terminal RFout is connected, and a ground wiring 104 to which the ground terminal is connected. Signal wiring 102, signal wiring 103, and ground wiring 104 are provided on the upper surface of base 101.

A part of the transmission line pattern in wiring layer 121, which is connected to signal wiring 102 to which input terminal RFin is connected, is connected to a part (input of input matching circuit 11) of the transmission line pattern in wiring layer 122 via conductive via 141. Further, a part of the transmission line pattern in wiring layer 121, which is connected to signal wiring 103 to which output terminal RFout is connected, is connected to a part (output of Doherty network 42) of the transmission line pattern in wiring layer 122 via conductive via 142. The ground pattern of wiring layer 121 is connected to the ground patterns in wiring layers 122, 123, 124, 125, and 126 via conductive vias 151, 153, 155, 156, and 157, and the like. A conductive via for grounding may be provided in dielectric layer 132.

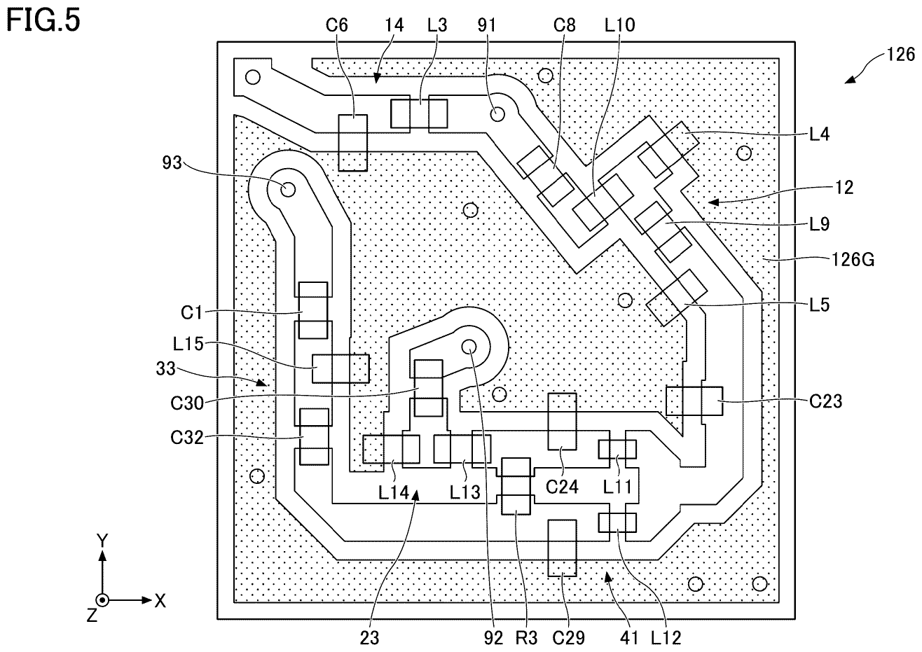

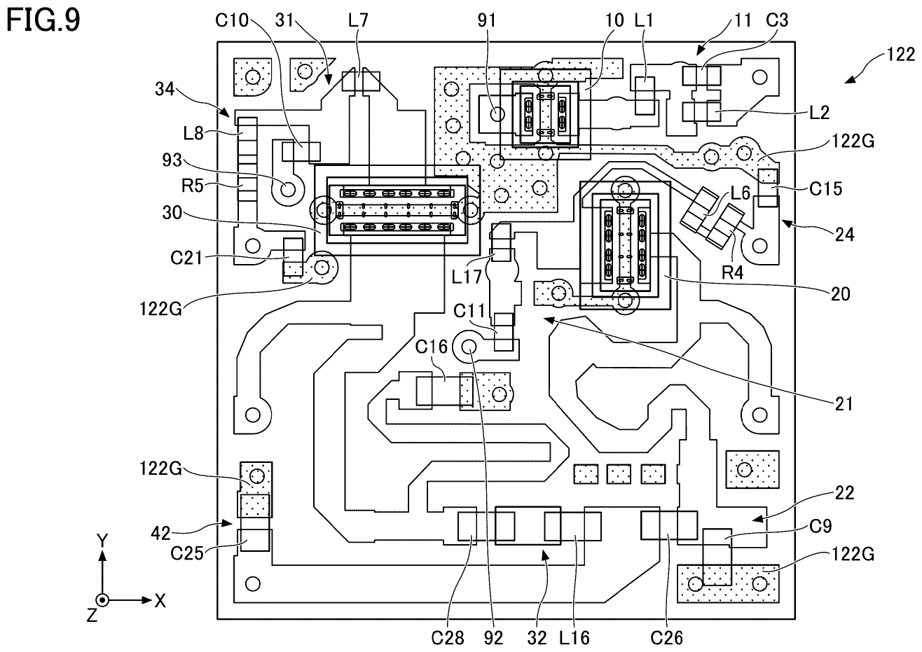

A part of the transmission line pattern in wiring layer 122, which is connected to the drain pad (output terminal 19) of driver amplifier 10, is connected to a part (input of output matching circuit 12) of the transmission line pattern in wiring layer 126 via one conductive via 144 (a conductive via 91 in FIGS. 5 and 9). A part of the transmission line pattern in wiring layer 126, which is connected to the output of phase adjusting circuit 23, is connected to a part (input of input matching circuit 21) of the transmission line pattern in wiring layer 122 via one conductive via 144 (a conductive via 92 in FIGS. 5 and 9). A part of the transmission line pattern in wiring layer 126, which is connected to the output of phase adjusting circuit 33, is connected to a part (input of input matching circuit 31) of the transmission line pattern in wiring layer 122 via one conductive via 144 (a conductive via 93 in FIGS. 5 and 9).

A part of the transmission line pattern in wiring layer 122 is connected to a part of the electrode pattern in wiring layer 123 via conductive via 143.

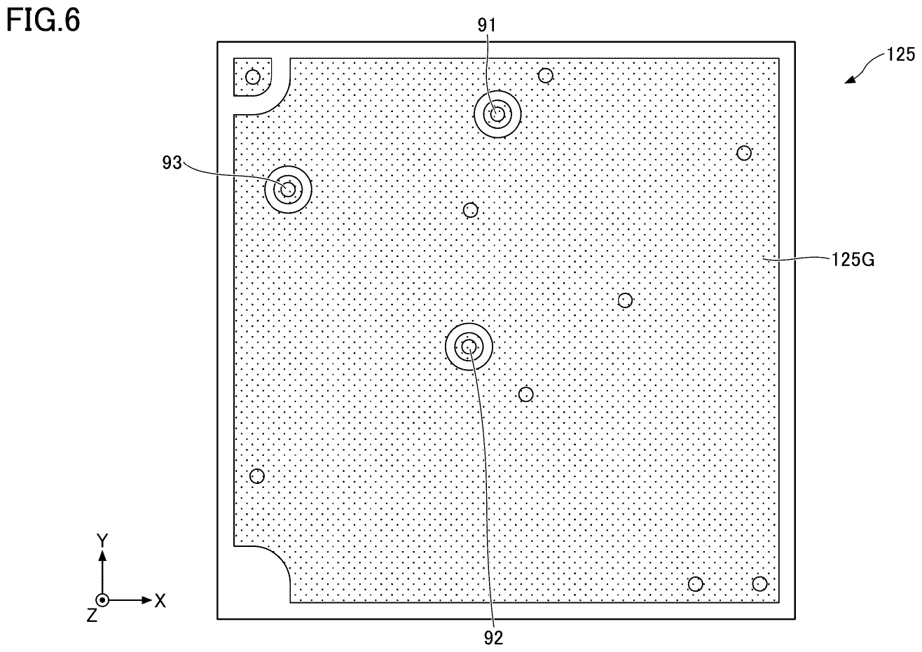

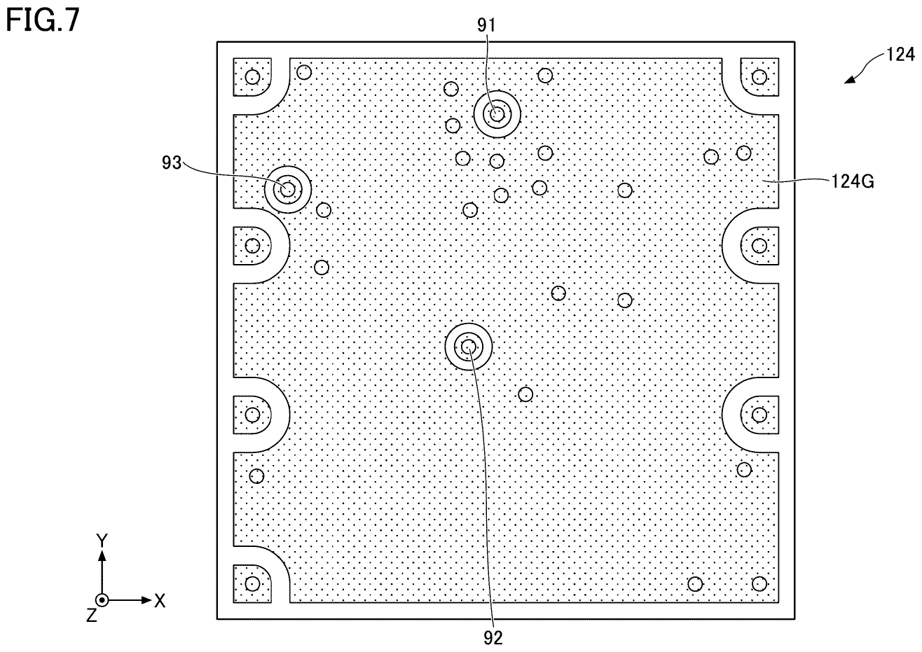

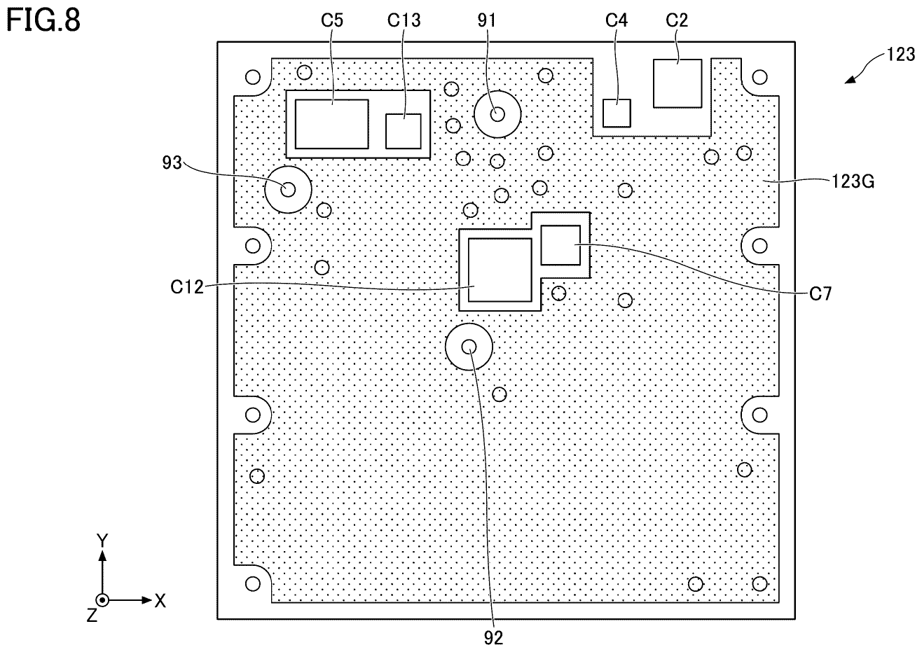

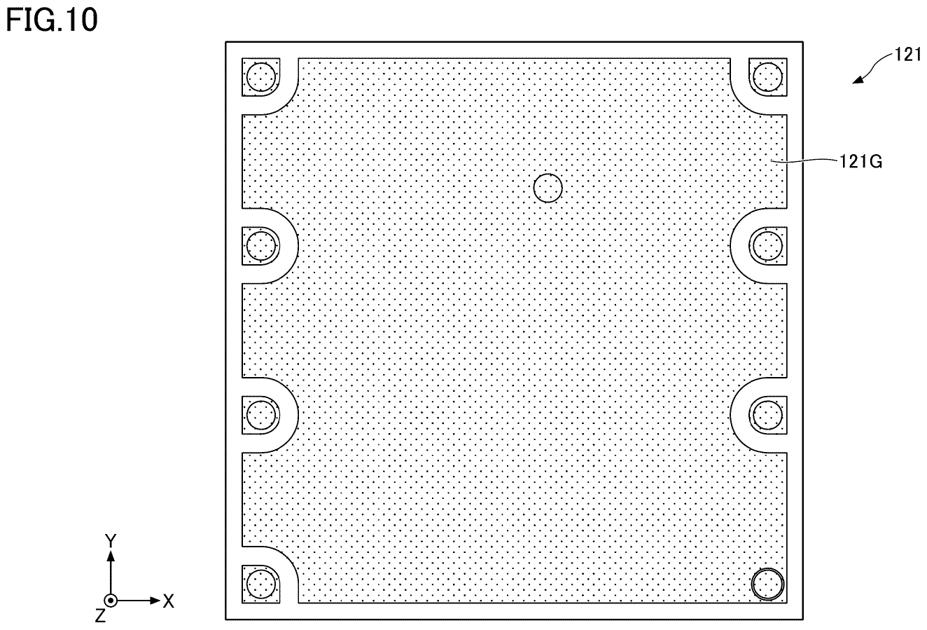

Next, the layout of each wiring layer will be described. FIG. 5 is a diagram illustrating the layout of wiring layer 126. FIG. 6 is a diagram illustrating the layout of wiring layer 125. FIG. 7 is a diagram illustrating the layout of wiring layer 124. FIG. 8 is a diagram illustrating the layout of wiring layer 123. FIG. 9 is a diagram illustrating the layout of wiring layer 122. FIG. 10 is a diagram illustrating the layout of wiring layer 121. In FIGS. 5 to 10, the ground pattern is provided with a matte finish (dot-like pattern). FIG. 5 also illustrates surface mount components 52, and FIG. 9 also illustrates surface mount components 51, driver amplifier 10, carrier amplifier 20, and peak amplifier 30.

As illustrated in FIG. 5, a ground pattern 126G, a transmission line pattern constituting output bias circuit 14, and a transmission line pattern constituting output matching circuit 12 are formed in wiring layer 126. A transmission line pattern constituting branch circuit 41, a transmission line pattern constituting phase adjusting circuit 23, and a transmission line pattern constituting phase adjusting circuit 33 are further formed in wiring layer 126. On the upper surface of the transmission line pattern in wiring layer 126, capacitors C6, C8, C23, C24, C29, C30, C32, and C1, inductors L3, L10, L4, L9, L5, L11, L12, L13, L14, and L15, and resistor element R3 are mounted as surface mount components 52.

As illustrated in FIG. 6, a ground pattern 125G is formed in a solid state in wiring layer 125. An opening through which conductive via 144 penetrates is formed in wiring layer 125.

As illustrated in FIG. 7, a ground pattern 124G is formed in a solid state in wiring layer 124. An opening through which conductive via 144 penetrates is formed in wiring layer 124.

As illustrated in FIG. 8, a ground pattern 123G is formed in a solid state in wiring layer 123. An electrode pattern of capacitor C2 or C4 of input matching circuit 11, an electrode pattern of capacitor C12 or C7 of input matching circuit 21, and an electrode pattern of capacitor C5 or C13 of input matching circuit 31 are further formed in wiring layer 123. An opening through which conductive via 144 penetrates is formed in wiring layer 123.

As illustrated in FIG. 9, a ground pattern 122G, a transmission line pattern constituting input matching circuit 11, and a transmission line pattern constituting Doherty network 42 are formed in wiring layer 122. A transmission line pattern constituting input matching circuit 21, a transmission line pattern constituting input bias circuit 24, and a transmission line pattern constituting output matching circuit 22 are further formed in wiring layer 122. A transmission line pattern constituting input matching circuit 31, a transmission line pattern constituting input bias circuit 34, and a transmission line pattern constituting output matching circuit 32 are further formed in wiring layer 122. On the lower surface of the transmission line patterns in wiring layer 122, capacitors C3, C11, C15, C9, C26, C10, C21, C28, C16, and C25, inductors L1, L2, L17, L6, L7, L8, and L16, and resistor elements R4 and R5 are mounted as surface mount components 51.

As illustrated in FIG. 10, a ground pattern 121G is formed in a solid state in wiring layer 121.

Output terminal 19 of driver amplifier 10 and input terminal 28 of carrier amplifier 20 may be adjacent to each other. However, when the spatial distance between output terminal 19 of driver amplifier 10 and input terminal 28 of carrier amplifier 20 is small and the phase difference of the RF signal between output terminal 19 and input terminal 28 is small (including the same phase), there is a possibility that the state becomes electrically unstable. For example, oscillation may occur.

In contrast, when the phase of the RF signal is in antiphase between output terminal 19 of driver amplifier 10 and input terminal 28 of carrier amplifier 20, the electrically unstable state can be made less likely to occur. For example, when the electrical length between output terminal 19 of driver amplifier 10 and input terminal 28 of carrier amplifier 20 is within a range of (2n+1)×π−π/2 to (2n+1)×π+π/2 in terms of a phase of a wavelength λ of the RF signal input to input terminal RFin, the phase of the RF signal is close to the antiphase, and the electrically unstable state can be made less likely to occur. That is, even when driver amplifier 10 and carrier amplifier 20 are close to each other, the electrical characteristics of carrier amplifier 20 can be easily stabilized. Here, n is an integer of 0 or more.

Output terminal 19 of driver amplifier 10 and input terminal 38 of peak amplifier 30 may be adjacent to each other. However, when the spatial distance between output terminal 19 of driver amplifier 10 and input terminal 38 of peak amplifier 30 is small and the phase difference of the RF signal between output terminal 19 and input terminal 38 is small (including the same phase), there is a possibility that the state becomes electrically unstable. For example, oscillation may occur.

In contrast, when the phase of the RF signal is in antiphase between output terminal 19 of driver amplifier 10 and input terminal 38 of peak amplifier 30, the electrically unstable state can be made less likely to occur. For example, when the electrical length between output terminal 19 of driver amplifier 10 and input terminal 38 of peak amplifier 30 is within a range of (2n+1)×π−π/2 to (2n+1)×π+π/2 in terms of a phase of wavelength λ of the RF signal input to input terminal RFin, the phase of the RF signal is close to the antiphase, and the electrically unstable state can be made less likely to occur. That is, even when driver amplifier 10 and peak amplifier 30 are close to each other, the electrical characteristics of peak amplifier 30 can be easily stabilized.

In the embodiment, wiring layer 126 has the transmission line pattern illustrated in FIG. 5, so that the electrical length between output terminal 19 of driver amplifier 10 and input terminal 38 of peak amplifier 30 is within a range of (2n+1)×π−π/2 to (2n+1)×π+π/2. Specifically, for example, in FIG. 5, the transmission line pattern from the output terminal (drain output) of driver amplifier 10 to branch circuit 41 is largely routed from the center to the right half. Further, phase adjusting circuit 23 is provided between branch circuit 41 and carrier amplifier 20, and phase adjusting circuit 33 is provided between branch circuit 41 and peak amplifier 30. In addition, the transmission line pattern from the output of branch circuit 41 to conductive via 92 and the transmission line pattern from the output of branch circuit 41 to conductive via 93 are not linear but curved.

Further, heat generated in driver amplifier 10 is transferred from main surface 10b to wiring layer 121, heat generated in carrier amplifier 20 is transferred from main surface 20b to wiring layer 121, and heat generated in peak amplifier 30 is transferred from main surface 30b to wiring layer 121. The heat transferred to wiring layer 121 is discharged to the outside via ground wiring 104 of printed circuit board 100.

### (Operation of High Frequency Amplifier)

Next, the operation of high frequency amplifier 1 will be described.

An RF signal input to input terminal RFin (a part of wiring layer 121) via signal wiring 102 reaches wiring layer 122 via conductive via 141, and is input to driver amplifier 10 via input matching circuit 11 provided in wiring layer 122. The RF signal amplified by driver amplifier 10 is directed to wiring layer 126 via conductive via 91. Then, the RF signal is transmitted to branch circuit 41 via output matching circuit 12 in wiring layer 126, and is branched into first signal line 41A and second signal line 41B by branch circuit 41.

The RF signal output to first signal line 41A is input to phase adjusting circuit 23. Phase adjusting circuit 23 delays the phase of the input RF signal (the input signal of carrier amplifier 20) by a predetermined distribution constant and outputs the delayed signal. On the other hand, the RF signal output to second signal line 41B is input to phase adjusting circuit 33. Phase adjusting circuit 33 delays the phase of the input RF signal (the input signal of peak amplifier 30) by a predetermined distribution constant and outputs the delayed signal. The RF signal output from phase adjusting circuit 23 is directed to wiring layer 122 via conductive via 92 and is input to carrier amplifier 20 via input matching circuit 21. The RF signal output from phase adjusting circuit 33 is directed to wiring layer 122 via conductive via 93 and is input to peak amplifier 30 via input matching circuit 31.

In asymmetrical Doherty amplifier 40, peak amplifier 30 and carrier amplifier 20 exhibit different maximum output intensities with respect to the input RF signal from each other. For example, peak amplifier 30 has a saturation output (size) that is about twice as large as that of carrier amplifier 20, and peak amplifier 30 initiates the amplifying operation in a case where the output of carrier amplifier 20 has reached the saturation region. Specifically, carrier amplifier 20 operates in class AB or class B, and peak amplifier 30 operates in class C. When the instantaneous power is small, carrier amplifier 20 operates and peak amplifier 30 does not operate, so that the power efficiency is improved. When the instantaneous power is large, both carrier amplifier 20 and peak amplifier 30 operate, and thus the saturation power can be increased while maintaining high power efficiency. When the saturation output of peak amplifier 30 is larger than the saturation output of carrier amplifier 20, the phase shift amount for obtaining the optimum matching in peak amplifier 30 is larger than that in carrier amplifier 20.

For example, driver amplifier 10 has a size sufficient for 10 W output, carrier amplifier 20 has a size sufficient for 15 W output, and peak amplifier 30 has a size sufficient for 30 W output. In this case, the current consumption or the power consumption may increase in the order of driver amplifier 10, carrier amplifier 20, and peak amplifier 30. The magnitude of heat generation associated with the operation may also increase in the order of driver amplifier 10, carrier amplifier 20, and peak amplifier 30.

The RF signal amplified by carrier amplifier 20 is input to Doherty network 42 via output matching circuit 22, and the RF signal amplified by peak amplifier 30 is input to Doherty network 42 via output matching circuit 32. Then, the RF signal output from Doherty network 42 reaches output terminal RFout (a part of wiring layer 121) via conductive via 142, and is output via signal wiring 103.

### (Method of Manufacturing High Frequency Amplifier)

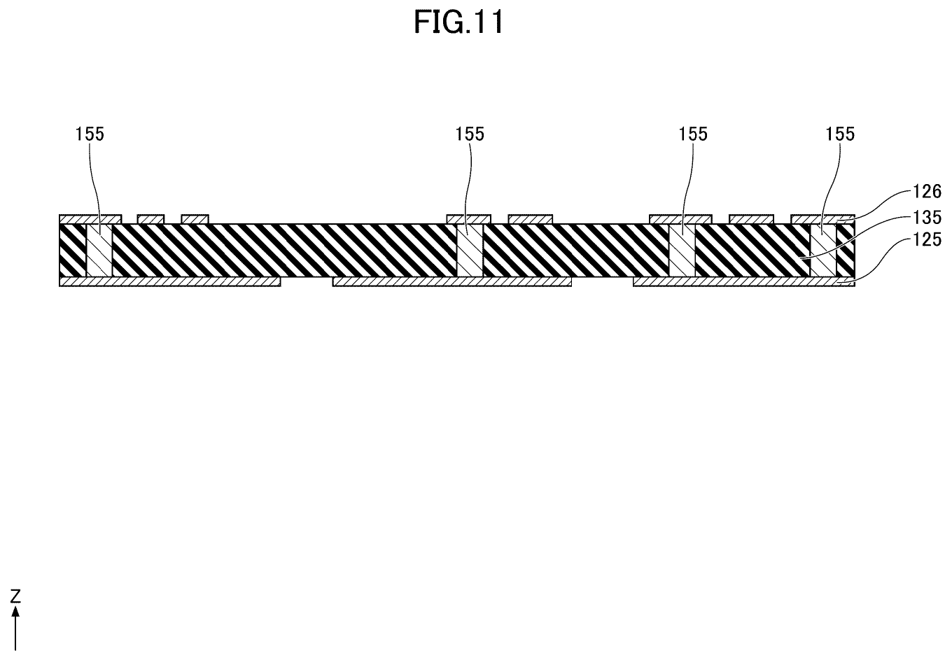

Next, a method of manufacturing high frequency amplifier 1 will be described. FIGS. 11 to 17 are cross-sectional views each illustrating the method of manufacturing the high frequency amplifier according to the embodiment.

First, as illustrated in FIG. 11, a layered body is produced in which wiring layer 125 is formed on the lower surface of dielectric layer 135, wiring layer 126 is formed on the upper surface of dielectric layer 135, and conductive vias 155 are formed inside dielectric layer 135. The layered body can be produced using, for example, a copper-clad laminate. At this time, the parts of wiring layer 126 overlapping conductive via 144, 156, or 157 are not formed.

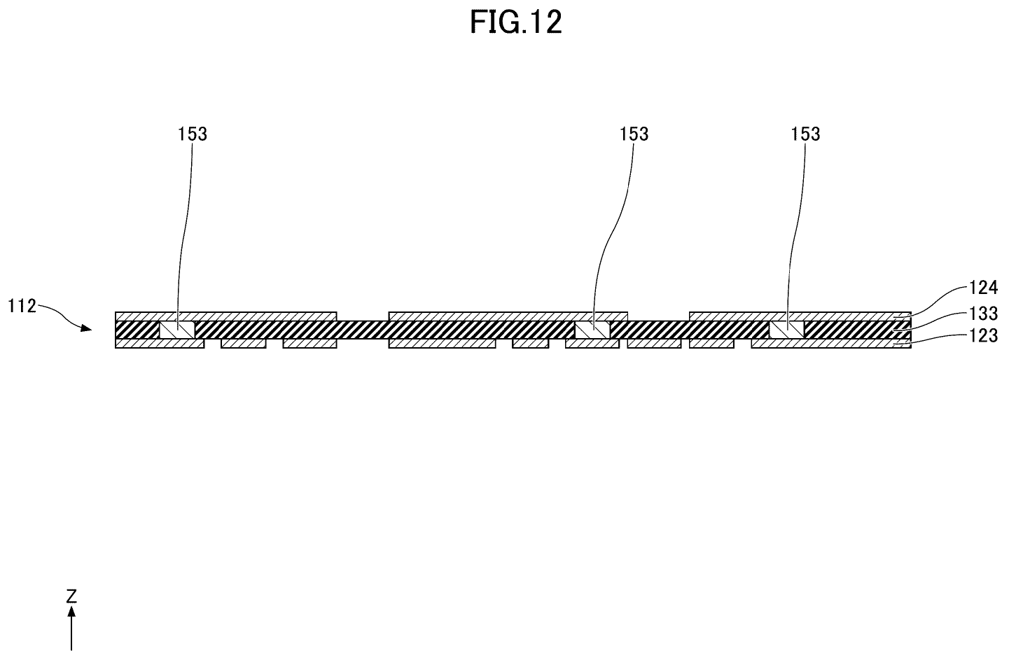

As illustrated in FIG. 12, second layered structure 112 is produced in which wiring layer 123 is formed on the lower surface of dielectric layer 133, wiring layer 124 is formed on the upper surface of dielectric layer 133, and conductive vias 153 are formed in dielectric layer 133. Second layered structure 112 can be produced using, for example, a copper-clad laminate.

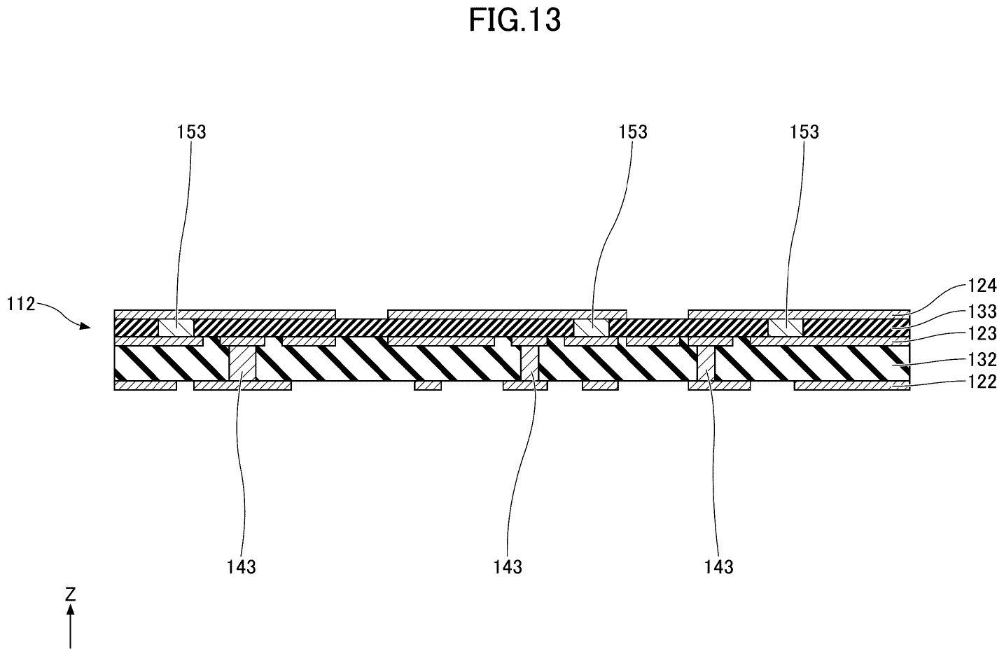

Next, as illustrated in FIG. 13, dielectric layer 132, wiring layer 122 and conductive via 143 are formed under second layered structure 112. At this time, the parts of wiring layer 122 overlapping conductive via 144 or 157 are not formed.

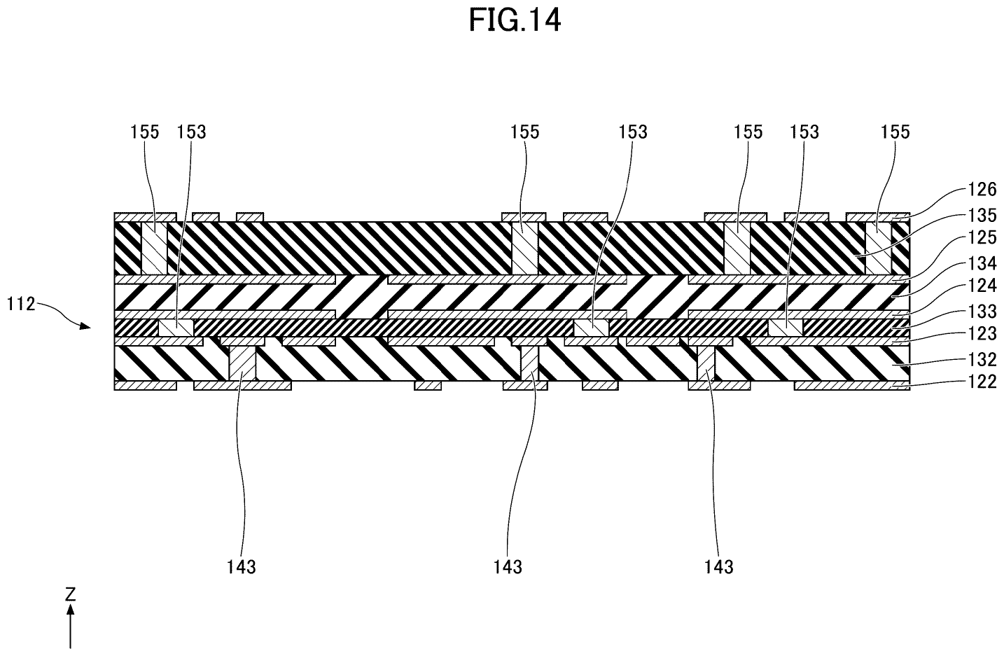

Next, as illustrated in FIG. 14, the layered body illustrated in FIG. 11 is superposed over the layered body illustrated in FIG. 13 with dielectric layer 134 being interposed therebetween.

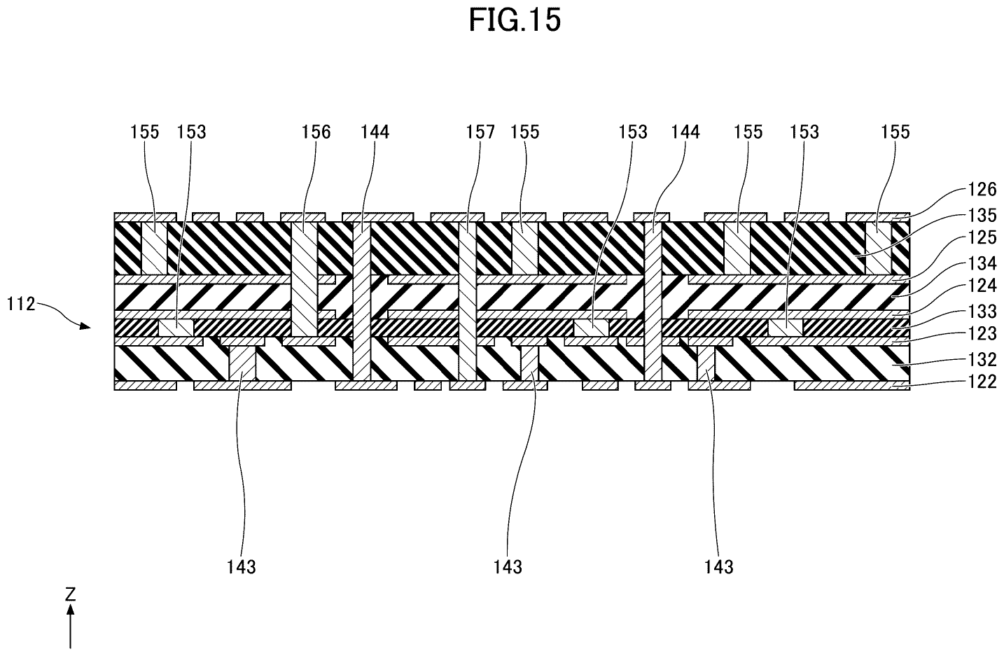

Next, as illustrated in FIG. 15, conductive vias 144, 156 and 157 are formed. At this time, a part of wiring layer 126 overlapping conductive vias 144, 156, or 157 and a part of wiring layer 122 overlapping conductive vias 144, 156, or 157 are formed.

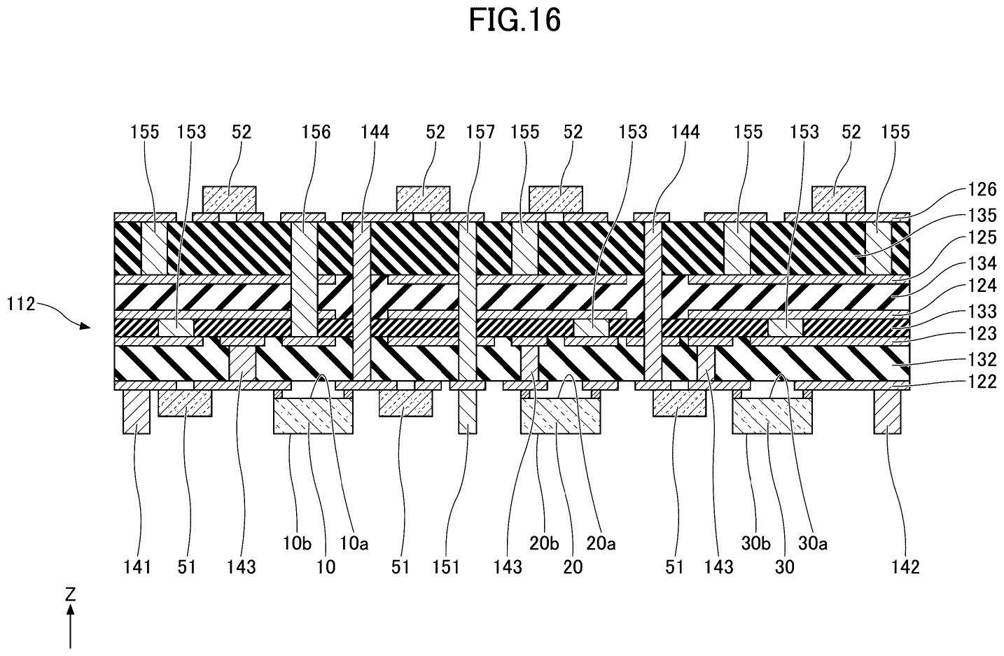

Next, as illustrated in FIG. 16, surface mount component 52 is mounted on the upper surface of wiring layer 126, and surface mount component 51, driver amplifier 10, carrier amplifier 20, and peak amplifier 30 are mounted on the lower surface of wiring layer 122. Conductive vias 141 and 142 are provided on the lower surface of wiring layer 122. Conductive vias 141 and 142 may be made of copper.

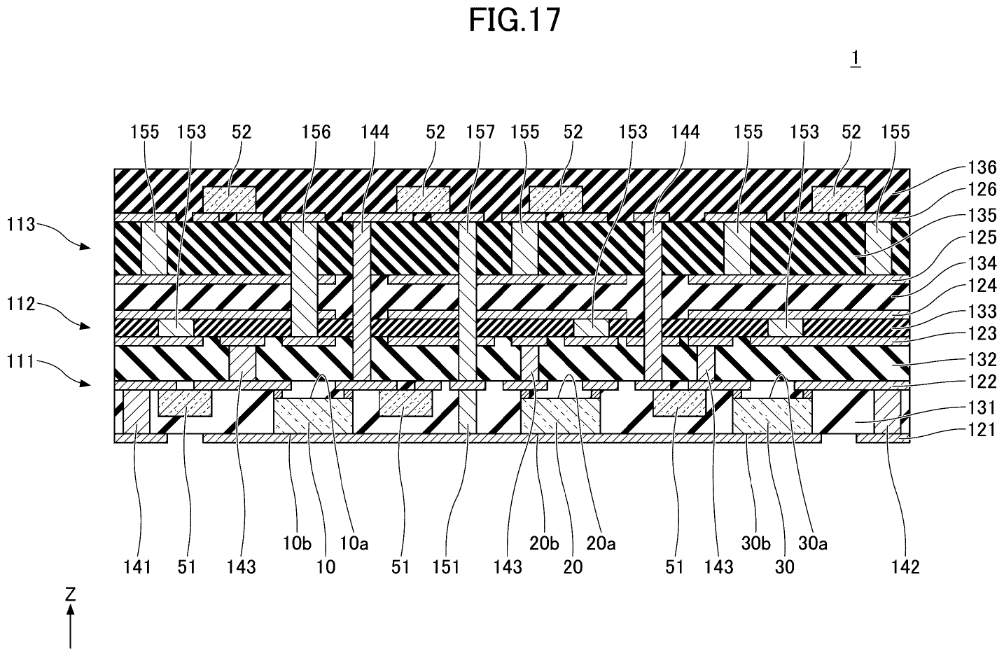

Next, as illustrated in FIG. 17, dielectric layer 136 is formed on or over dielectric layer 135, dielectric layer 131 is formed under dielectric layer 132, and wiring layer 121 is formed under dielectric layer 131. In forming dielectric layer 131, a dielectric layer to be dielectric layer 131 is formed thicker than dielectric layer 131, and then the dielectric layer is polished so that main surface 10b of driver amplifier 10, main surface 20b of carrier amplifier 20, and main surface 30b of peak amplifier 30 are exposed. Wiring layer 121 includes a ground pattern in contact with main surface 10b of driver amplifier 10, main surface 20b of carrier amplifier 20, and main surface 30b of peak amplifier 30, a transmission line pattern in contact with conductive via 141, and a transmission line pattern in contact with conductive via 142.

In this way, high frequency amplifier 1 according to the embodiment can be manufactured.

In high frequency amplifier 1, second layered structure 112 including wiring layer 123, dielectric layer 133, and wiring layer 124 is provided between driver amplifier 10, carrier amplifier 20, and peak amplifier 30; and branch circuit 41, phase adjusting circuit 23, and phase adjusting circuit 33. Thus, interference of signals between driver amplifier 10, carrier amplifier 20, and peak amplifier 30; and branch circuit 41, phase adjusting circuit 23, and phase adjusting circuit 33 is less likely to occur, and the high frequency characteristics can be improved.

Further, the uniformity of the line length between capacitors C2, C4, C7, C12, C5, and C13 and the input of driver amplifier 10, carrier amplifier 20, or peak amplifier 30 can be increased, and the high frequency characteristics can be improved.

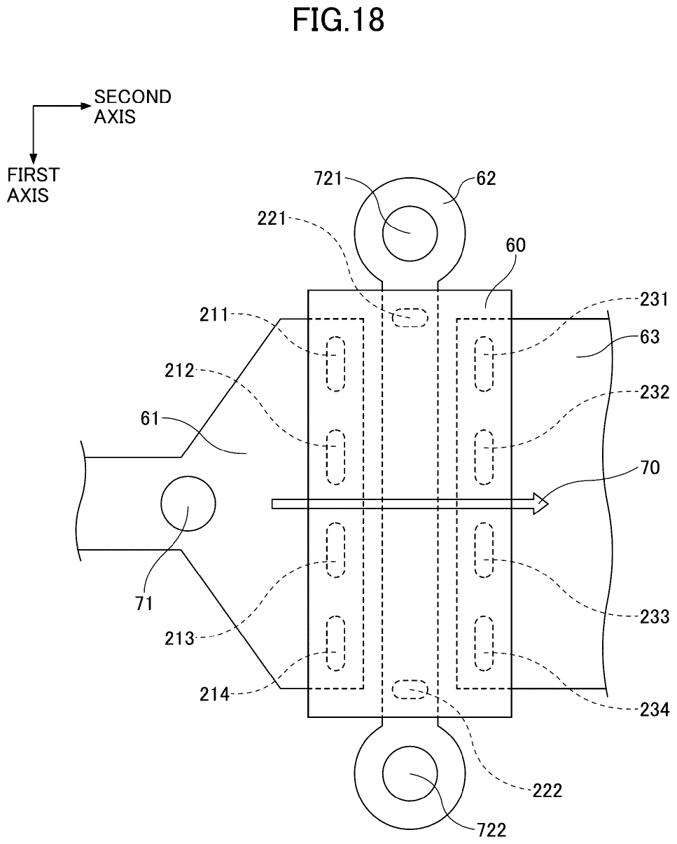

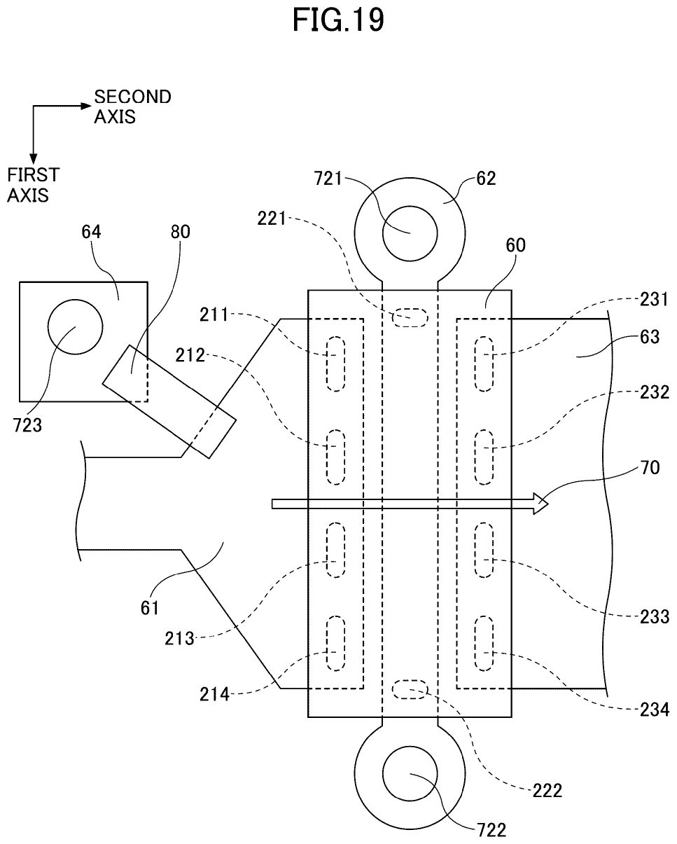

The high frequency characteristics of the amplifiers in two examples with different forms of capacitors will be further described with reference to FIGS. 18 and 19. FIG. 18 is a diagram illustrating a layout in a first example, and FIG. 19 is a diagram illustrating a layout in a second example.

In the first example illustrated in FIG. 18, an amplifier 60 includes gate terminals 211, 212, 213 and 214, source terminals 221 and 222, and drain terminals 231, 232, 233 and 234.

Gate terminals 211, 212, 213, and 214 are arranged in this order along the first axis. Gate terminals 211, 212, 213 and 214 are connected to a wiring layer 61. Wiring layer 61 is connected to a capacitor via a conductive via 71. This capacitor is provided in second layered structure 112, as in high frequency amplifier 1.

Source terminals 221 and 222 are arranged in this order along the first axis. Source terminal 221 is located farther in the positive direction of the second axis, which is perpendicular to the first axis, than the row of gate terminals 211, 212, 213, and 214. Source terminal 221 is located farther in the negative direction of the first axis than gate terminal 211, and source terminal 222 is located farther in the positive direction of the first axis than gate terminal 214. Source terminals 221 and 222 are connected to a wiring layer 62. Wiring layer 62 is grounded via conductive vias 721 and 722. Conductive via 721 is located farther in the negative direction of the first axis than amplifier 60, and conductive via 722 is located farther in the positive direction of the first axis than amplifier 60.

Drain terminals 231, 232, 233, and 234 are arranged in this order along the first axis. Drain terminals 231, 232, 233 and 234 are located farther in the positive direction of the second axis than the row of source terminals 221 and 222. Drain terminal 231 is located farther in the positive direction of the first axis than source terminal 221, and drain terminal 234 is located farther in the negative direction of the first axis than source terminal 222. Drain terminals 231, 232, 233 and 234 are connected to a wiring layer 63.

An input signal of amplifier 60 is input to wiring layer 61. Further, the output signal of amplifier 60 is output to wiring layer 63. In amplifier 60, the signal flows as indicated by an arrow 70. Driver amplifier 10, carrier amplifier 20, and peak amplifier 30 in high frequency amplifier 1 may have the same structure as amplifier 60.

In amplifier 60, the signal line length between conductive via 71 and gate terminal 211 can be made equal to the signal line length between conductive via 71 and gate terminal 214. Further, the signal line length between conductive via 71 and gate terminal 212 can be made equal to the signal line length between conductive via 71 and gate terminal 213.

In the second example illustrated in FIG. 19, a wiring layer 64 is provided, and a capacitor of a surface mount component 80 is provided between wiring layer 61 and wiring layer 64. Wiring layer 64 is grounded via a conductive via 723. The other configuration of the second example is the same as that of the first example.

In the second example, the difference in signal line length between the capacitor and gate terminals 211, 212, 213, and 214 is larger than that in the first example.

As described above, in the first example, the difference in signal line length between each of gate terminals 211, 212, 213, and 214 of amplifier 60 and the capacitor is made smaller than that in the second example, and excellent high frequency characteristics are obtained.

Also, capacitors C2, C4, C7, C12, C5, and C13 are formed in the second layered structure 112, and the surface mount components of these capacitors are not required. Thus, the number of surface mount components can be reduced as compared with the case where the surface mount components of these capacitors are used.

For example, since capacitors C2 and C4 are included in input matching circuit 11, the number of surface mount components in input matching circuit 11 can be reduced. Further, since capacitors C7 and C12 are included in input matching circuit 21, the number of surface mount components in input matching circuit 21 can be reduced. Further, since capacitors C5 and C13 are included in input matching circuit 31, the number of surface mount components in input matching circuit 31 can be reduced.

The parasitic resistance and the parasitic inductance of capacitors C2, C4, C7, C12, C5, and C13 formed in the second layered structure 112 are smaller than those in the case where a surface mount component such as a multilayer ceramic capacitor is used. Thus, matching (high frequency matching) of the RF signal can be performed with low impedance.

Furthermore, since the ground pattern of wiring layer 123 is formed in a solid state, even if the relative dielectric constant of dielectric layer 133 is high, the influence of dielectric layer 133 on the RF signal transmitted via the transmission line pattern of wiring layer 122 can be reduced. In particular, output matching circuit 22, output matching circuit 32, and Doherty network 42 are easily affected by parasitic capacitance caused by the surrounding dielectric layer. When a ground pattern (ground region) is provided in a part of wiring layer 123 that overlaps, in a plan view, with the transmission line pattern constituting output matching circuit 22, a part of wiring layer 123 that overlaps, in a plan view, with the transmission line pattern constituting output matching circuit 32, and a part of wiring layer 123 that overlaps, in a plan view, with Doherty network 42, it is easy to reduce deterioration of the RF signal in output matching circuit 22, output matching circuit 32, and Doherty network 42.

Note that, when one of phase adjusting circuits 23 and 33 is provided, the other does not need to be provided. For example, phase adjusting circuit 33 does not need to be provided as long as phase adjusting circuit 23 is provided, and phase adjusting circuit 23 does not need to be provided as long as phase adjusting circuit 33 is provided.

Further, a base member made of metal, such as copper, may be used instead of wiring layer 121. In this case, main surface 10b of driver amplifier 10, main surface 20b of carrier amplifier 20, and main surface 30b of peak amplifier 30 can be fixed to the base member and electrically connected to the base member by using, for example, a sintered material of silver or copper.

Although the embodiments have been described in detail, the present disclosure is not limited to the specific embodiments, and various modifications and changes can be made within the scope described in the claims.

What is claimed is:

1. A high frequency amplifier including a driver amplifier configured to amplify an input high frequency signal and an asymmetrical Doherty amplifier configured to amplify a high frequency signal output from the driver amplifier, the high frequency amplifier comprising:
a first layered structure;
a second layered structure layered on the first layered structure; and
a third layered structure layered on the second layered structure,
wherein the asymmetrical Doherty amplifier includes:
a carrier amplifier;
a peak amplifier configured to initiate an amplifying operation in a case where an output of the carrier amplifier has reached a saturation region, the peak amplifier having a saturation output different from a saturation output of the carrier amplifier;
a branch circuit configured to receive the high frequency signal output from the driver amplifier;
a first signal line provided between the branch circuit and the carrier amplifier;
a second signal line provided between the branch circuit and the peak amplifier; and
a phase adjusting circuit provided in either one or both of the first signal line and the second signal line and configured to delay either one or both of a phase of an input signal to the carrier amplifier and a phase of an input signal to the peak amplifier,
wherein the branch circuit is configured to branch the high frequency signal output from the driver amplifier into the first signal line and the second signal line,
wherein the second layered structure includes:
a first wiring layer provided between the first layered structure and the third layered structure;
a second wiring layer provided between the first wiring layer and the third layered structure;
a dielectric layer provided between the first wiring layer and the second wiring layer; and
one or more capacitors including a part of the first wiring layer, a part of the second wiring layer, and a part of the dielectric layer,
wherein the driver amplifier, the carrier amplifier, and the peak amplifier are provided in the first layered structure,
wherein the branch circuit and the phase adjusting circuit are provided in the third layered structure, and
wherein the one or more capacitors are each electrically connected to any one of the driver amplifier, the carrier amplifier, and the peak amplifier.

2. The high frequency amplifier according to claim 1, further comprising:
a first input matching circuit including the one or more capacitors and connected to an input terminal of the driver amplifier.

3. The high frequency amplifier according to claim 2, wherein the first input matching circuit is provided in the first layered structure and the second layered structure.

4. The high frequency amplifier according to claim 1, further comprising:
a second input matching circuit including the one or more capacitors and connected to an input terminal of the carrier amplifier.

5. The high frequency amplifier according to claim 4, wherein the second input matching circuit is provided in the first layered structure and the second layered structure.

6. The high frequency amplifier according to claim 1, further comprising
a third input matching circuit including the one or more capacitors and connected to an input terminal of the peak amplifier.

7. The high frequency amplifier according to claim 6, wherein the third input matching circuit is provided in the first layered structure and the second layered structure.

8. The high frequency amplifier according to claim 1, wherein the first wiring layer has at least a ground region overlapping, in a plan view, with a transmission line through which a high frequency signal output from the carrier amplifier or the peak amplifier is transmitted.

9. The high frequency amplifier according to claim 1, wherein when n is an integer of 0 or more, an electrical length from an output terminal of the driver amplifier to an input terminal of the carrier amplifier is within a range of (2n+1)×π−π/2 to (2n+1)×π+π/2, inclusive, according to a calculation in terms of a phase of the high frequency signal.

10. The high frequency amplifier according to claim 1, wherein when n is an integer of 0 or more, an electrical length from an output terminal of the driver amplifier to an input terminal of the peak amplifier is within a range of (2n+1)×π−π/2 to (2n+1)×π+π/2, inclusive, in terms of a phase of the high frequency signal.

11. The high frequency amplifier according to claim 1, wherein
the saturation output of the peak amplifier is larger than the saturation output of the carrier amplifier.
